(19) United States
(12) Patent Application Publication
(10) Pub. No.: US 2025/0174516 A1
(43) Pub. Date: May 29, 2025

(54) SEMICONDUCTOR DEVICE

(71) Applicant: FUJI ELECTRIC CO., LTD., Kawasaki-shi (JP)

(72) Inventors: Tsubasa WATAKABE, Matsumoto-city (JP); Yuko NAKAMATA, Matsumoto-city (JP); Motohito HORI, Matsumoto-city (JP)

(73) Assignee: FUJI ELECTRIC CO., LTD., Kawasaki-shi (JP)

(21) Appl. No.: 18/930,268

(22) Filed: Oct. 29, 2024

(30) Foreign Application Priority Data
Nov. 29, 2023 (JP) 2023-201310

(51) Int. Cl. H01L 23/373; H01L 23/00; H01L 23/31; H01L 23/42; H01L 23/538; H01L 25/00; H01L 25/065

(52) U.S. Cl. CPC H01L 23/3737; H01L 23/42; H01L 25/0655; H01L 23/3121; H01L 23/5385; H01L 24/16; H01L 24/32; H01L 24/73; H01L 25/50; H01L 2224/16225; H01L 2224/32225; H01L 2224/73253

(57) ABSTRACT

A semiconductor device, including: a semiconductor module including a metal plate at a back surface thereof, the metal plate having a bottom surface; a cooling module including a cooling surface on which the bottom surface of the metal plate is placed; and an adhesion member provided between the bottom surface of the metal plate and the cooling surface, the adhesion member containing electrically conductive fillers that connect the bottom surface and the cooling surface.

### CROSS-REFERENCE TO RELATED APPLICATION

This application is based upon and claims the benefit of priority of the prior Japanese Patent Application No. 2023-201310, filed on Nov. 29, 2023, the entire contents of which are incorporated herein by reference.

### BACKGROUND OF THE INVENTION

### 1. Field of the Invention

The embodiment discussed herein relates to a semiconductor device.

### 2. Background of the Related Art

There are proposed semiconductor devices in which a semiconductor module is disposed on a cooling module via a joining member to dissipate heat (see, for example, Japanese Laid-open Patent Publication No. 2023-103785). The joining member contains, for example, an organic resin or solder as a major component (see, for example, Japanese Laid-open Patent Publications No. 2018-046166 and No. 2021-111765).

### SUMMARY OF THE INVENTION

According to an aspect, there is provided a semiconductor device including a semiconductor module including a metal plate at a back surface thereof, the metal plate having a bottom surface; a cooling module including a cooling surface on which the bottom surface of the metal plate is placed; and an adhesion member provided between the bottom surface of the metal plate and the cooling surface, the adhesion member containing electrically conductive fillers that connect the bottom surface and the cooling surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a lateral cross-sectional view of a semiconductor device according to an embodiment;

FIG. 2 is a lateral cross-sectional view of an adhesion member of the semiconductor device according to the embodiment;

FIG. 3 is a flowchart illustrating a method for manufacturing the semiconductor device of the embodiment;

FIG. 4 is a first diagram for describing a semiconductor module assembly step of the embodiment;

FIG. 5 is a second diagram for describing the semiconductor module assembly step of the embodiment;

FIG. 6 is a lateral cross-sectional view of the semiconductor module of the embodiment;

FIG. 7 is a back view of the semiconductor module of the embodiment;

FIG. 8 is a first diagram for describing a heating step of the embodiment; and

FIG. 9 is a second diagram for describing the heating step of the embodiment.

### DETAILED DESCRIPTION OF THE INVENTION

An embodiment will be described below with reference to the accompanying drawings. In the following, the terms “front surface” and “top surface” refer to the X-Y plane facing upward (the +Z direction) in a semiconductor device of the drawings. Similarly, the term “upper” refers to the upward direction (the +Z direction) of the illustrated semiconductor device. On the other hand, the terms “back surface” and “bottom surface” refer to the X-Y plane facing downward (the −Z direction) in the illustrated semiconductor device. Similarly, the term “lower” refers to the downward direction (the −Z direction) of 41 the illustrated semiconductor device. These terms have the same orientational relationships in all drawings if needed. “High” and “upper” in position refer to upper positions (the +Z direction) in the illustrated semiconductor device. On the other hand, “low” and “lower” in position refer to lower positions (the −Z direction) in the illustrated semiconductor device. The terms “front surface”, “top surface”, “upper”, “back surface”, “bottom surface”, “lower”, and “lateral surface” are simply expedient expressions used to specify relative positional relationships, and are not intended to limit the technical ideas of the embodiment described herein. For example, the terms “upper” and “lower” do not necessarily imply the vertical directions to the ground surface. That is, the “upper” and “lower” directions are not defined in relation to the direction of the gravitational force. In addition, the term “major component” in the following refers to a constituent having a concentration equal to 80 vol % or higher. The phrase “substantially the same” refers to where two or more things being compared have a difference of no more than ±10%. In addition, the terms “perpendicular”, “orthogonal”, and “parallel” may also include substantially perpendicular, substantially orthogonal, and substantially parallel, as appropriate, which may include a margin of error of ±10° or less.

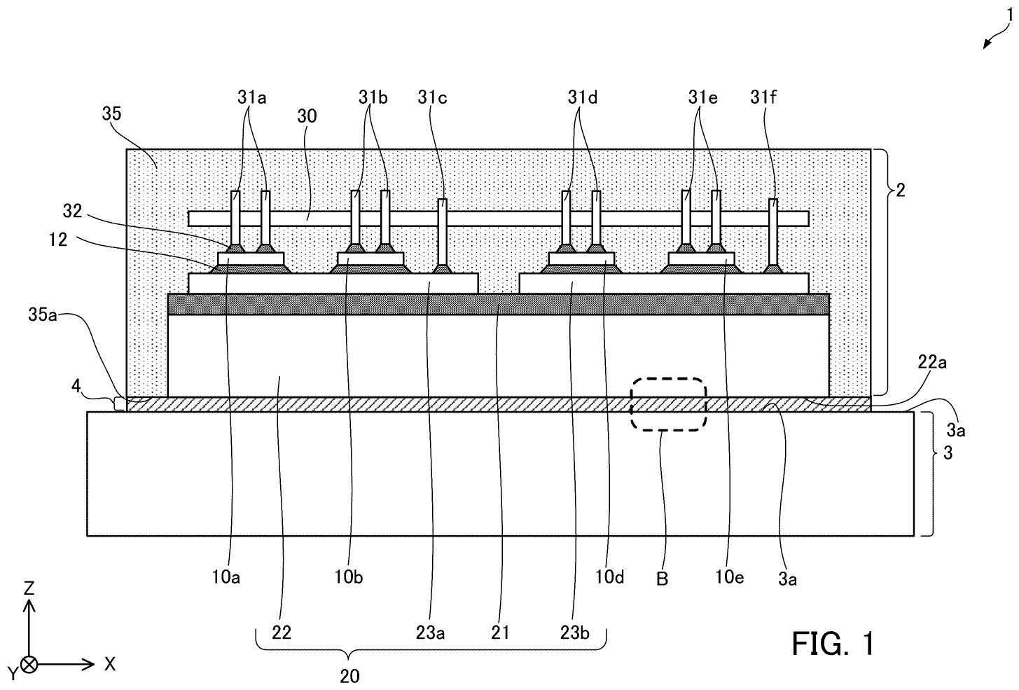

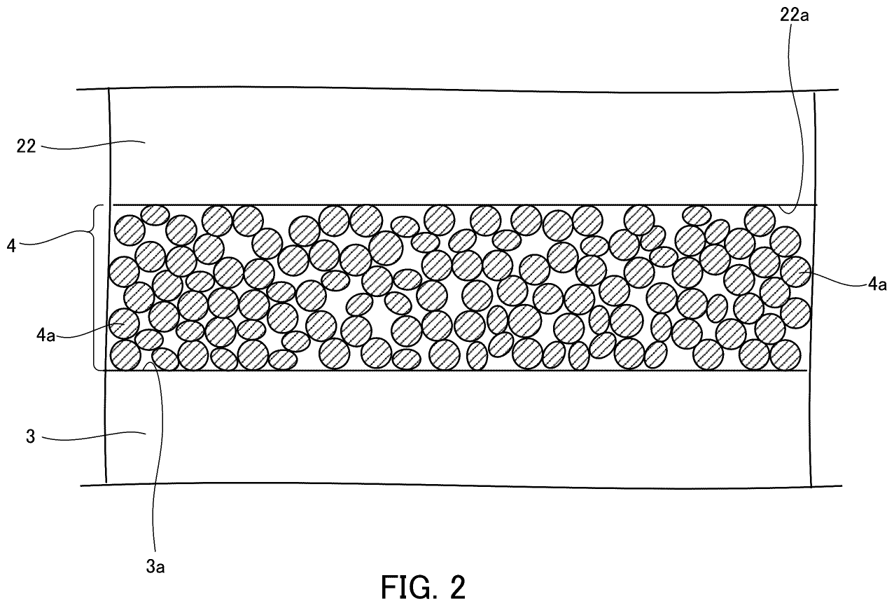

A semiconductor device 1 according to an embodiment is described next with reference to FIGS. 1 and 2. FIG. 1 is a lateral cross-sectional view of a semiconductor device according to the embodiment. FIG. 2 is a lateral cross-sectional view of an adhesion member of the semiconductor device according to the embodiment. Note that the cross section of FIG. 1 is obtained when a plane parallel to the Z-X plane cuts through the center of the semiconductor device 1 in plan view, as viewed in the +Y direction. FIG. 2 is an enlarged view of Region B in an adhesion member 4 of FIG. 1. Region B is an example of a region including the adhesion member 4. Also, in other regions of the adhesion member 4, fillers 4a are included between a bottom surface 22a of a metal plate 22 and a cooling surface 3a of a cooling module 3, as in Region B.

The semiconductor device 1 includes a semiconductor module 2, the cooling module 3, and the adhesion member 4 for fixing the semiconductor module 2 and the cooling module 3. Note that the semiconductor device 1 may include other needed components in addition to the aforementioned ones.

The semiconductor module 2 includes semiconductor chips 10a, 10b, 10d, and 10e, an insulated circuit board 20, a printed circuit board 30, and a sealing member 35 for sealing the foregoing components. The semiconductor chips 10a, 10b, 10d, and 10e may be power metal-oxide-semiconductor field-effect transistors (power MOSFETs) whose major component is silicon carbide. In each power MOSFET, a body diode may function as a free wheeling diode (FWD). The semiconductor chips 10a, 10b, 10d, and 10e each have, for example, an input electrode (drain electrode) functioning as a main electrode on the back surface, and an output electrode (source electrode) functioning as a main electrode and control electrodes (gate electrode) on the front surface. The control electrodes may be provided at the center of one side of the front surface of the individual semiconductor chips 10a, 10b, 10d, and 10e, or may be provided offset from the center along the side.

Alternatively, the semiconductor chips 10a, 10b, 10d, and 10e may include a switching element containing silicon as a major component. The switching element is, for example, a reverse-conducting insulated gate bipolar transistor (RC-IGBT). The RC-IGBT is a semiconductor element having a single-chip structure with a circuit where an IGBT is connected antiparallel with an FWD.

Each of the above semiconductor chips 10a, 10b, 10d, and 10e has an input electrode (collector electrode) functioning as a main electrode on the back surface, and an output electrode (emitter electrode) functioning as a main electrode and control electrodes (gate electrode) on the front surface. The control electrodes may be provided at the center of one side of the front surface of each of the semiconductor chips 10a, 10b, 10d, and 10e, or may be provided offset from the center along the side, as in the case of the power MOSFETs described above.

Alternatively, the semiconductor chips 10a, 10b, 10d, and 10e may, for example, be semiconductor chips containing silicon as a major component and each including a switching element or a diode element. Specifically, the semiconductor chips 10a and 10d may be switching elements while the semiconductor chips 10b and 10e may be diode elements. The switching elements are, for example, power MOSFETS or IGBTs. Each semiconductor chip including a switching element has, for example, an input electrode (drain electrode in the case of a power MOSFET; and collector electrode in the case of an IGBT) functioning as a main electrode on the back surface, and a gate electrode functioning as control electrodes and an output electrode (source electrode in the case of a power MOSFET; and emitter electrode in the case of an IGBT) functioning as a main electrode on the front surface. As for the diode elements, for example, Schottky barrier diodes (SBD) or P-intrinsic-N (PiN) diodes are used as FWDs. Each semiconductor chip including a diode element has an output electrode (cathode electrode) functioning as a main electrode on the back surface, and an input electrode (anode electrode) functioning as a main electrode on the front surface.

The semiconductor chips 10a and 10b and the semiconductor chips 10d and 10e described above are individually bonded to conductive patterns 23a and 23b (to be described later), respectively, with solder 12. The solder 12 is made up of solder components. The solder components constituting the solder 12 include lead-free solder containing a predetermined alloy as a major component. The predetermined alloy includes tin. Such an alloy is, for example, at least one of the followings: a tin-silver alloy, a tin-silver-copper alloy, a tin-zinc-bismuth alloy, a tin-copper alloy, a tin-silver-indium-bismuth alloy, and a tin-antimony alloy. Further, the solder components may include an additive, such as nickel, germanium, cobalt, or silicon. Thus, the solder components are, for example, made of tin and at least one of silver, zinc, copper, bismuth, indium, and antimony. Further, the solder components may include at least one of nickel, germanium, cobalt, and silicon, for example. The thickness of the solder 12 is 50 μm or more and 300 μm or less. Note that the solder components of solder 32 described below are the same as those of the solder 12. Sintered compacts may be used instead of the solder 12. A sintered material of the sintered compacts used in bonding here is, for example, a powder of silver, iron, copper, aluminum, titanium, nickel, tungsten, or molybdenum.

The insulated circuit board 20 includes an insulating plate 21, the metal plate 22, and the conductive patterns 23a and 23b. The insulating plate 21 and the metal plate 22 have a rectangular shape in plan view. In addition, the insulating plate 21 and the metal plate 22 may have R- or C-chamfered corners.

The insulating plate 21 is made of, for example, The resin may be a material with low thermal a resin. resistance and high insulation capability. For example, a thermosetting resin exhibits such properties. The thermosetting resin may contain fillers. The thermal resistance of the insulating plate 21 may be further reduced by controlling the material and content of the fillers. Further, according to the fillers, the linear expansion coefficient of the insulating plate 21 and those of the metal plate 22 and the conductive patterns 23a and 23b described later may be made approximately equal. Reducing the difference in linear expansion coefficients suppresses the occurrence of warpage in the insulated circuit board 20 due to the difference in the linear expansion coefficients even if the insulated circuit board 20 is subject to thermal changes. In this case, the difference in linear expansion coefficients may be within a margin of error of 10% or more and 50% or less.

Such a thermosetting resin is, for example, at least one of the following: epoxy resin, cyanate resin, polyimide resin, benzoxazine resin, unsaturated polyester resin, phenol resin, melamine resin, silicone resin, maleimide resin, acrylic resin, and polyamide resin. The fillers are made of at least one of oxide and nitride. Example of the oxide include silicon oxide and aluminum oxide. Examples of the nitride include silicon nitride, aluminum nitride, and boron nitride. Furthermore, hexagonal boron nitride may be used as the fillers. The thickness of the insulating plate 21 depends on the rated voltage of the semiconductor device 1. That is, the thickness of the insulating plate 21 needs to be increased as the rated voltage of the semiconductor device 1 is higher. On the other hand, the thickness of the insulating plate 21 needs to be as thin as possible from the viewpoint of lowering thermal resistance.

The insulating plate 21 may be a ceramic substrate instead of a resin plate. The ceramic substrate is made of ceramic with excellent thermal conductivity. The ceramic here is made of a material containing, for example, aluminum oxide, aluminum nitride, or silicon nitride as a major component. As the insulated circuit board 20 including the insulating plate 21 having such a composition, for example, a direct copper bonding (DCB) board or an active metal brazed (AMB) board may be used.

Note that, according to this embodiment, the insulating plate 21 is made of resin, and the difference between the linear expansion coefficient of the insulating plate 21 and the linear expansion coefficients of the metal plate 22 and the conductive patterns 23a and 23b is designed to be small.

The metal plate 22 is made of a metal having excellent thermal conductivity. The material is, for example, copper, aluminum, or an alloy made of at least one of these. Here, the material contains copper. Plating may be applied to coat the surfaces of the metal plate 22 in order to provide improved corrosion resistance. In this case, a material used for plating contains nickel. Such a plating material is, for example, nickel, a nickel-phosphorus alloy, or a nickel-boron alloy. Note that the bottom surface 22a of the metal plate 22 is also the bottom surface of the insulated circuit board 20. The bottom surface 22a of the metal plate 22 is exposed from a bottom surface 35a of the sealing member 35 to be described later. In this case, the bottom surface 22a of the metal plate 22 may protrude outward from the bottom surface 35a of the sealing member 35, or may be flush with the bottom surface 35a of the sealing member 35. According to this embodiment, the bottom surface 22a of the metal plate 22 is flush with the bottom surface 35a of the sealing member 35. The thickness of the metal plate 22 may be three times or more and fifteen times or less than the thickness of the insulating plate 21.

On the conductive patterns 23a and 23b, the semiconductor chips 10a and 10b and the semiconductor chips 10d and 10e, respectively, are disposed. The conductive patterns 23a and 23b are formed all over the insulating plate 21, except for its rims. In plan view, edges of the conductive patterns 23a and 23b, facing the outer periphery of the insulating plate 21, may coincide with edges of the metal plate 22, facing the outer periphery of the insulating plate 21. In this case, in the insulated circuit board 20, stress balance with the metal plate 22 placed on the back surface of the insulating plate 21 is maintained. This reduces damage to the insulating plate 21, such as excessive warpage and crack formation.

The conductive patterns 23a and 23b are made of a material with excellent electrical conductivity. The material is, for example, copper, aluminum, or an alloy made of at least one of these. Plating may be applied to the conductive patterns 23a and 23b using a material with excellent corrosion resistance. In this case, the material used for plating is, for example, nickel, a nickel-phosphorus alloy, or a nickel-boron alloy. The conductive patterns 23a and 23b on the insulating plate 21 are created by forming a metal plate on the front surface of the insulating plate 21 and performing etching or the like on the metal plate. Alternatively, the conductive patterns 23a and 23b preliminarily cut out of a metal plate are bonded to the front surface of the insulating plate 21. Note that the conductive patterns 23a and 23b included in the semiconductor device 1 of the embodiment are merely an example, and appropriate changes may be made to the number of conductive patterns, their shape, size and so on, on an as-needed basis.

The printed circuit board 30 includes an insulating layer and multiple upper circuit pattern layers formed on the front surface of the insulating layer. The printed circuit board 30 may also include multiple lower circuit pattern layers on the back surface of the insulating layer. The printed circuit board 30 with such a configuration opposes the front surface of the insulated circuit board 20 in plan view. In addition, the printed circuit board 30 is electrically connected to the output electrodes, input electrodes, and control electrodes of the semiconductor chips 10a, 10b, 10d, and 10e. Note that conductive posts 31a, 31b, 31d, and 31e depicted in FIG. 1 are only an example, and conductive posts not illustrated in FIG. 1 may also be included. The upper parts of the conductive posts 31a, 31b, 31d, and 31e, together with those of the conductive posts not illustrated, are electrically connected to the upper circuit pattern layers and the lower circuit pattern layers of the printed circuit board 30 while their lower parts are connected to the output electrodes and control electrodes of the semiconductor chips 10a, 10b, 10d, and 10e with the solder 32.

For example, the printed circuit board 30 is electrically connected to the output electrodes on the front surfaces of the semiconductor chips 10a and 10b through the conductive posts 31a and 31b, and is also electrically connected to the output electrodes on the front surfaces of the semiconductor chips 10d and 10e through the conductive posts 31d and 31e.

The printed circuit board 30 is electrically connected to the input electrodes on the back surfaces of the semiconductor chips 10a and 10b via a conductive post 31c and the conductive pattern 23a, and is also electrically connected to the input electrodes on the back surfaces of the semiconductor chips 10d and 10e via a conductive post 31f and the conductive pattern 23b.

The printed circuit board 30 is electrically connected to the control electrodes of the semiconductor chips 10a and 10b via a conductive post (not illustrated), and is also electrically connected to the control electrodes of the semiconductor chips 10d and 10e via a conductive post (not illustrated).

The sealing member 35 seals the insulated circuit board 20, the semiconductor chips 10a, 10b, 10d, and 10e, and the printed circuit board 30 as a whole. Various terminals, for example, for input, output, and control, may protrude from the top surface of the sealing member 35 if needed. The sealing member 35 may be, for example, a rectangular parallelepiped, and includes the flat bottom surface 35a. The bottom surface 22a of the metal plate 22 of the insulated circuit board 20 is exposed from the bottom surface 35a of the sealing member 35.

The foregoing sealing member 35 may be a thermosetting resin containing fillers. That is, the sealing member 35 is made of insulating fillers and a resin (thermosetting resin) to be described later as major components. In this case, the thermosetting resin is, for example, an epoxy resin, a phenolic resin, a maleimide resin, or a polyester resin. The fillers may be made of ceramic having insulting properties and high thermal conductivity as a major component. Such fillers are, for example, silicon oxide, aluminum oxide, boron nitride, or aluminum nitride. The content of the fillers is 10 volume % or more and 70 volume % or less of the entire sealing member 35.

The semiconductor module 2 having such a configuration is merely an example. The semiconductor module 2 may be formed, for example, in the following order: disposing a DCB board and semiconductor chips on a heat dissipation base in order; wiring the DBC board and the semiconductor chips; disposing a case on the heat dissipation base such as to surround the DBC board and the semiconductor chips; and sealing the inside of the case with a sealing member. In this case, the bottom surface of the heat dissipation base corresponds to the bottom surface 22a of the metal plate 22.

The cooling module 3 has the cooling surface 3a on its top surface, on which the semiconductor module 2 is placed. The cooling surface 3a is flat and wider than the back surface of the semiconductor module 2. The cooling module 3 may be, for example, a heat dissipation base having heat dissipation fins, or a cooling device with a refrigerant circulating therein.

The adhesion member 4 is provided between the bottom surface 22a of the metal plate 22 of the semiconductor module 2 and the cooling surface 3a of the cooling module 3 to bond these two surfaces. Herewith, the adhesion member 4 fixes the semiconductor module 2 and the cooling module 3 and also thermally connects the metal plate 22 and the cooling module 3. The adhesion member 4 simply needs to be in contact with at least the entire bottom surface 22a of the metal plate 22 of the semiconductor module 2. The adhesion member 4 illustrated in FIG. 1 remains within the back surface of the semiconductor module 2, which includes the bottom surface 22a of the metal plate 22 of the semiconductor module 2, and is in contact with the entire back surface. That is, the adhesion member 4 does not spread outward from any lateral surface of the semiconductor module 2. Note however that the adhesion member 4 may spread outward from the lateral surfaces of the semiconductor module 2 to the entire cooling surface 3a.

The foregoing adhesion member 4 is an organic resin adhesive containing thermosetting resin as a major component and includes the electrically conductive fillers 4a (see FIG. 2). The thermosetting resin is, for example, an epoxy resin, a phenolic resin, or a polyimide resin. Here, an epoxy resin is used. The adhesive strength of the adhesion member 4 is, for example, 10 MPa or more. The adhesive strength here means tensile adhesive strength. The curing temperature of the adhesion member 4 is lower than the melting point of the solder 12 and 32, and may be, for example, 200° C. or less, preferably 175° C. or less, and more preferably 150° C. or less.

The fillers 4a of the adhesion member 4 may contain a conductive metal. The metal is, for example, silver, copper, gold, nickel, chromium, aluminum, or an alloy containing at least one of these. The fillers 4a may be, for example, spherical or flake shaped. The amount of the fillers 4a filled in the adhesion member 4 is 80% by weight or more. Note that the fillers 4a may mainly contain such a metal, and may contain inorganic fillers other than the metal. Such inorganic fillers are, for example, ceramic with high insulation and high thermal conductivity. The ceramic is, for example, at least one of aluminum oxide, aluminum nitride, silicon nitride, and boron nitride.

Within the adhesion member 4, the fillers 4a connect the bottom surface 22a of the metal plate 22 and the cooling surface 3a of the cooling module 3 together, as depicted in FIG. 2. That is, the fillers 4a form thermal paths between the bottom surface 22a of the metal plate 22 and the cooling surface 3a of the cooling module 3. This improves the thermal conductivity of the metal plate 22 to the cooling module 3. The fillers 4a may include portions that are sintered in the adhesion member 4.

The thermal conductivity of the adhesion member 4 containing the foregoing fillers 4a may be 10 W/mK or more. The material and amount of the fillers 4a may be selected so as to obtain the thermal conductivity. The adhesion member 4 may have lower elastic modulus than the solder 12 and 32 and the sintered material, for example, 10 GPa or less. The thickness of the adhesion member 4 may be 50 μm or more and 150 μm or less. On the other hand, the adhesion member 4 needs to be as thin as possible to offer low thermal resistivity (i.e., high thermal conductivity). However, if the thickness is less than 50 μm, the stress of the adhesion member 4 becomes large. Also, with the thickness being less than 50 μm, paths for volatile gas generated in the adhesion member 4 to escape are reduced, making it difficult to release the gas.

Here, as a reference example, a case will be described in which a joining member made of a different material is used in place of the adhesion member 4 of the semiconductor device 1. In the following description, a thermal interface material (hereinafter, TIM) is referred to as the joining member, and a case of using a TIM is described. Examples of the TIM include various materials, such as thermal conductive grease, an elastomer sheet, room temperature vulcanization (RTV) rubber, gel, and a phase change material.

When the joining member of the reference example is thermal conductive grease, which is a common TIM, the thermal conductivity is less than 5 W/mK. With such a joining member, there is a limit to reduction of thermal resistance even if the thickness of the joining member is further reduced.

In the semiconductor device 1 including the joining member of the reference example, when the cooling surface 3a of the cooling module 3 is deformed due to, for example, changes in temperature, the joining member between the bottom surface 22a of the metal plate 22 and the cooling surface 3a is likely to flow out from therebetween. When such a pump-out phenomenon occurs, the thermal conductivity from the semiconductor module 2 to the cooling module 3 decreases, thus leading to a decrease in the performance of the semiconductor module 2.

In addition, common TIMs provide poor adhesion. Using such a TIM as the joining member needs the use of a different structure and parts to fix the semiconductor module 2 and the cooling module 3. This makes the semiconductor device 1 a complicated structure and therefore increases manufacturing costs.

On the other hand, in the case of using an adhesive as the joining member, a common adhesive has insulating properties and a thermal conductivity of about 5 W/mK. Therefore, even if the common adhesive may be able to fix the semiconductor module 2 and the cooling module 3, it is difficult to reduce the thermal resistance, thus reducing the heat dissipation performance of the semiconductor device 1.

It is also possible to use solder or a sintered material as the joining member. However, solder and sintered materials have high joining temperatures. Therefore, when heat is applied to join the semiconductor module 2 and the cooling module 3 with such a joining member, the solder or sintered material in the semiconductor module 2 may melt. Furthermore, solder and sintered materials exhibit high elastic moduli. Therefore, in the semiconductor device 1 including the semiconductor module 2 and the cooling module 3 joined with such a joining member, stress is generated in the joining member during heat cycles, which leads to decreased reliability.

The semiconductor device 1 of the above embodiment includes the semiconductor module 2, the cooling module 3, and the adhesion member 4. The semiconductor module 2 includes the metal plate 22 having the bottom surface 22a on the back surface side. The cooling module 3 includes the cooling surface 3a on which the bottom surface 22a of the metal plate 22 is disposed. The adhesion member 4 is provided between the bottom surface 22a of the metal plate 22 and the cooling surface 3a, and contains the electrically conductive fillers 4a, which connect the bottom surface 22a and the cooling surface 3a to each other. In the foregoing semiconductor device 1, the semiconductor module 2 and the cooling module 3 are readily fixed only using the adhesion member 4 without a complicated structure. Further, the adhesion member 4 reduces the thermal resistivity between the semiconductor module 2 and the cooling module 3, thereby improving the heat dissipation performance of the semiconductor device 1.

In addition, because the adhesion member 4 has a low elastic modulus, even if the semiconductor device 1 undergoes heat cycles, stress generated in the adhesion member 4 is mitigated. Further, in the case where the insulating plate 21 of the insulated circuit board 20 is made of resin, the occurrence of warpage in the insulated circuit board 20 is suppressed even if the semiconductor device 1 undergoes heat cycles. Therefore, stress generated in the adhesion member 4 is further reduced. This makes it possible to reduce the thickness of the adhesion member 4 and thus render the adhesion member 4 low thermal resistance.

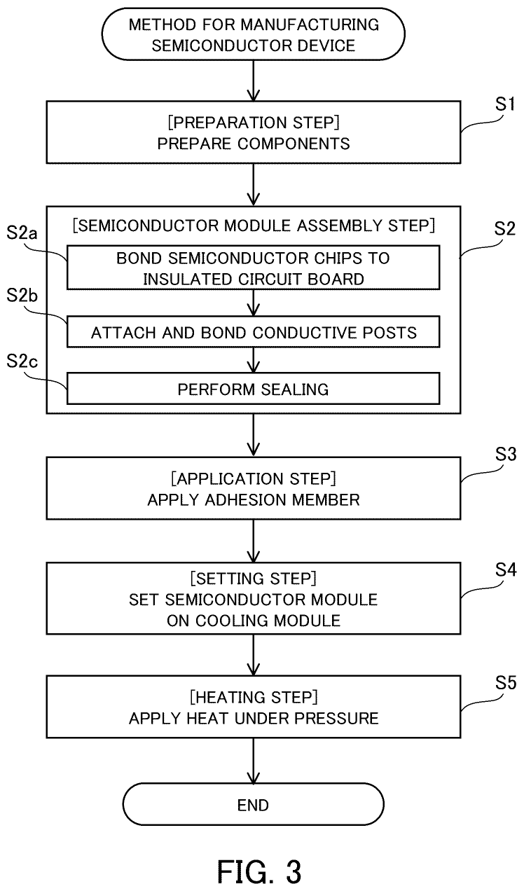

Next described is a method for manufacturing the foregoing semiconductor device 1, with reference to FIG. 3. FIG. 3 is a flowchart illustrating a method for manufacturing the semiconductor device of the embodiment. First, a preparation step is performed to prepare components of the semiconductor device 1 (step S1). The components prepared here are, for example, those making up the semiconductor module 2, that is, the semiconductor chips 10a, 10b, 10d, and 10e, the insulated circuit board 20, the printed circuit board 30 with the conductive posts 31a, 31b, 31c, 31d, 31e, and 31f, and the sealing member 35. In addition, the cooling module 3 is also prepared in this step. As well, components not specified here but needed for the manufacture of the semiconductor device 1 may also be prepared. Further, devices used for manufacturing the semiconductor device 1 may be prepared. The manufacturing devices include, for example, an applicator for applying solder and a molding device used for sealing with a sealing member.

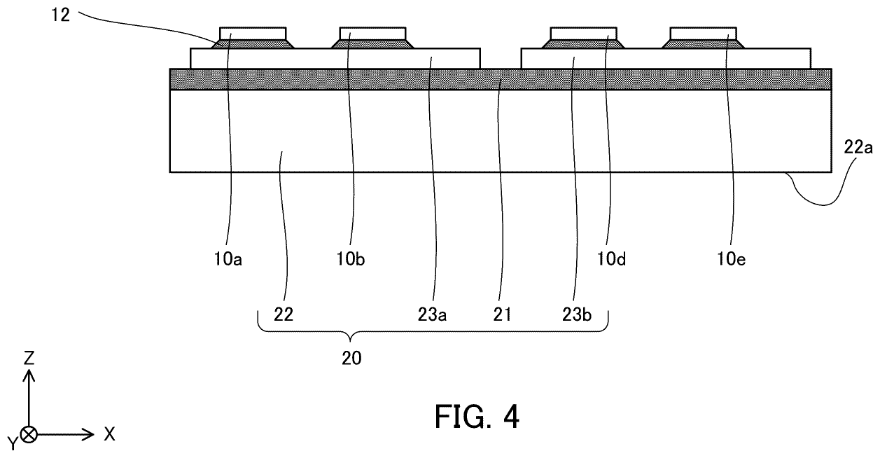

Next, a semiconductor module assembly step is performed to assemble the semiconductor module 2 (step S2). In the semiconductor module assembly step, the following steps are further performed. First, the semiconductor chips 10a, 10b, 10d, and 10e are bonded to the insulated circuit board 20 (step S2a). Step S2a is described with reference to FIG. 4. FIG. 4 is a first diagram for describing the semiconductor module assembly step of the embodiment.

The semiconductor chips 10a, 10b, 10d, and 10e are bonded to the conductive patterns 23a and 23b of the insulated circuit board 20 via the solder 12. Conventional solder bonding is used here. In this manner, a structure is obtained in which the semiconductor chips 10a and 10b are joined to the conductive pattern 23a of the insulated circuit board 20 via the solder 12 while the semiconductor chips 10d and 10e are bonded to the conductive pattern 23b via the solder 12, as depicted in FIG. 4.

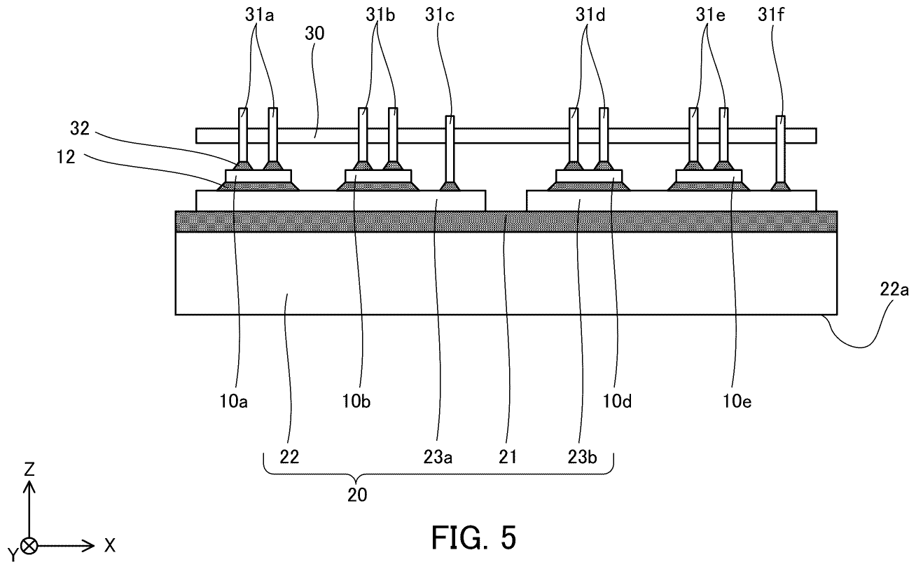

Then, the conductive posts 31a, 31b, 31c, 31d, 31e, and 31f of the printed circuit board 30 are individually bonded to the semiconductor chips 10a and 10b, the conductive pattern 23a of the insulated circuit board 20, the semiconductor chips 10d and 10e, and the conductive pattern 23b of the insulated circuit board 20 (step S2b). Step S2b is described with reference to FIG. 5. FIG. 5 is a second diagram for describing the semiconductor module assembly step of the embodiment.

The printed circuit board 30 is in advance provided with the conductive posts 31a, 31b, 31c, 31d, 31e, and 31f. The foregoing conductive posts 31a, 31b, 31c, 31d, 31e, and 31f are bonded by conventional soldering. In this manner, a structure is obtained in which the printed circuit board 30 is attached to the insulated circuit board 20, to which the semiconductor chips 10a, 10b, 10d, and 10e have been bonded, as depicted in FIG. 5.

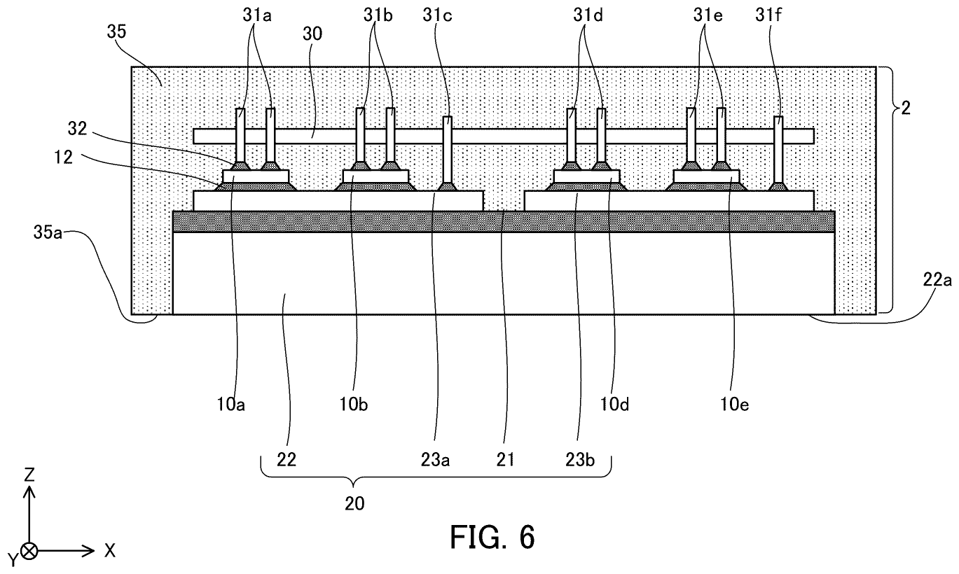

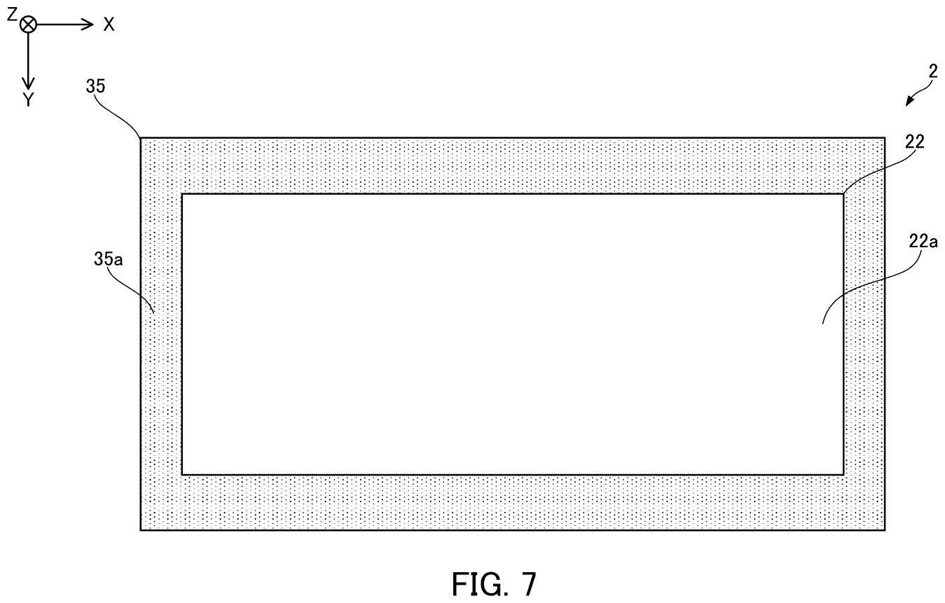

At the end of step S2, a sealing step is performed using the sealing member 35 (step (S2c). Step S2c is described with reference to FIGS. 6 and 7. FIG. 6 is a lateral cross-sectional view of the semiconductor module of the embodiment. FIG. 7 is a back view of the semiconductor module of the embodiment. Note that the back view of FIG. 7 depicting the back surface of the semiconductor module 2 is obtained when the semiconductor module 2 of FIG. 6 is viewed in +Z direction.

The structure obtained in step S2b is set, for example, in a predetermined mold. The sealing member 35 is filled into the mold to seal the structure. By removing the mold, the semiconductor module 2 depicted in FIG. 6 is obtained. In the semiconductor module 2, the bottom surface 22a of the metal plate 22 of the insulated circuit board 20 is exposed from the bottom surface 35a of the sealing member 35, as illustrated in FIG. 7. The bottom surface 35a of the sealing member 35 and the bottom surface 22a of the metal plate 22 are flush with each other. The back surface of the semiconductor module 2 is made up with the bottom surface 35a of the sealing member 35 and the bottom surface 22a of the metal plate 22.

Next, an application step is performed to apply the adhesion member 4 (step S3). The adhesion member 4 may be applied to either the back surface of the semiconductor module 2 or the cooling surface 3a of the cooling module 3. For example, the application of the adhesion member 4 may be performed as follows. First, a mask with a predetermined opening corresponding to an application area is set on the application surface. The adhesion member 4 is applied into the opening with a squeegee. The mask is then removed, and thus the adhesion member 4 is transferred to the application area. According to the embodiment, the adhesion member 4 corresponding to the size of the back surface of the semiconductor module 2 is applied to the placement area of the semiconductor module 2 on the cooling surface 3a of the cooling module 3. The adhesion member 4 may be applied with a dispenser.

Next, a setting step is performed in which the back surface of the semiconductor module 2 is set on the cooling surface 3a of the cooling module 3 via the adhesion member 4 (step S4). Here, the cooling module 3 is fixed to a predetermined fixing base, and the back surface of the semiconductor module 2 is placed onto the adhesion member 4 transferred to the cooling module 3.

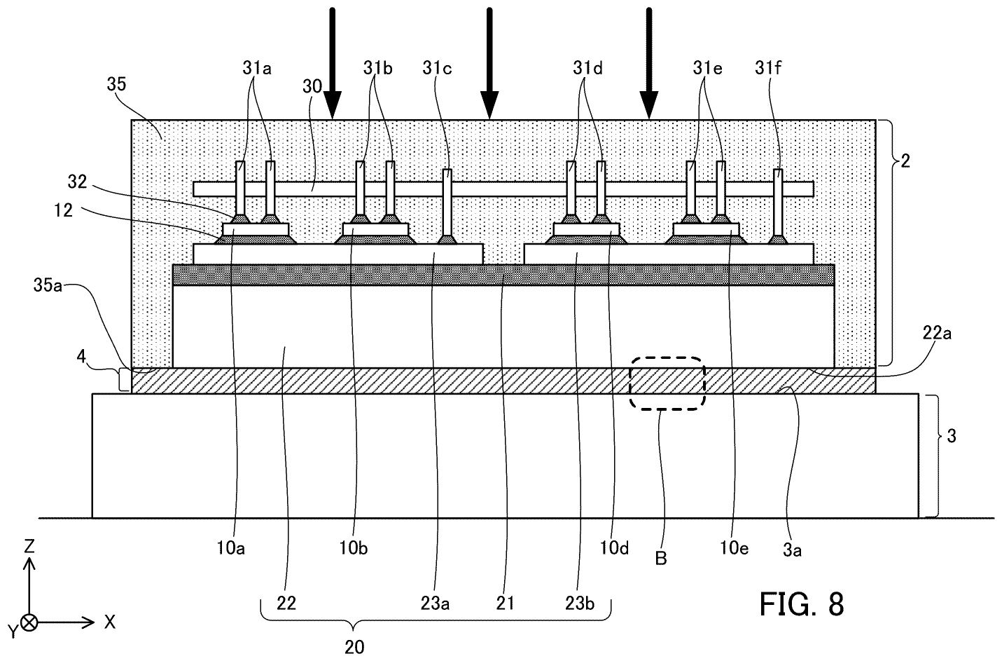

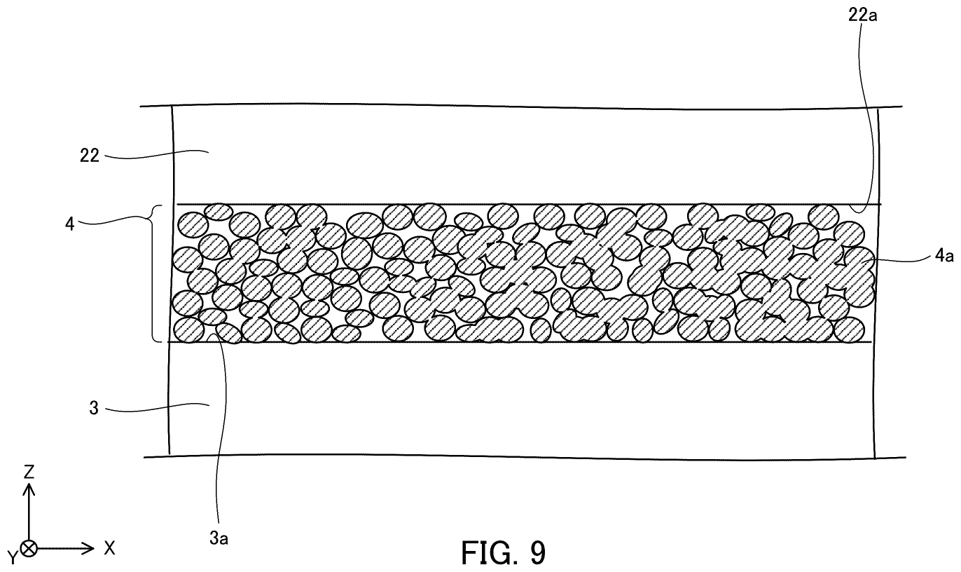

Next, a heating step is performed to heat the adhesion member 4 (step S5). The heating step is described with reference to FIGS. 8 and 9. FIG. 8 is a first diagram for describing the heating step of the embodiment. FIG. 9 is a second diagram for describing the heating step of the embodiment. A structure is heated which includes the cooling module 3 and the semiconductor module 2 disposed on the cooling surface 3a of the cooling module 3 via the adhesion member 4. The heating temperature here is 200° C. or less, preferably 175° C. or less, and more preferably 150° C. or less. This suppresses remelting of the solder 12 and 32 used in the semiconductor module 2. After heated in this manner, the adhesion member 4 hardens, and the semiconductor module 2 and the cooling module 3 are thereby joined together.

Alternatively, during heating described above, pressure may be applied such that the back surface of the semiconductor module 2 and the cooling surface 3a of the cooling module 3 come close to each other, as depicted in FIG. 8. According to FIG. 8, the top surface of the semiconductor module 2 is pressed against the cooling module 3 at, for example, about 0.1 MPa.

In this case, while the adhesion member 4 is heated, pressure is applied so that the bottom surface 22a of the metal plate 22 comes closer to the cooling surface 3a, whereby the fillers 4a contained in the adhesion member 4 are compressed together. Then, the fillers 4a may be partially sintered, as depicted in FIG. 9. This increases the density of the thermal paths between the bottom surface 22a of the metal plate 22 and the cooling surface 3a of the cooling module 3 compared to when no pressing operation is performed. This further improves the thermal conductivity of the metal plate 22 to the cooling module 3. Through the above flowchart of FIG. 3, the semiconductor device 1 depicted in FIGS. 1 and 2 is obtained.

According to an aspect, it is possible to readily fix the semiconductor module and the cooling module and also improve heat dissipation.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one embodiment of the present invention has been described in detail, it should be understood that various changes, substitutions, and alterations could be made hereto without departing from the spirit and scope of the invention.

What is claimed is:

1. A semiconductor device, comprising:
a semiconductor module including a metal plate at a back surface thereof, the metal plate having a bottom surface;
a cooling module including a cooling surface on which the bottom surface of the metal plate is placed; and
an adhesion member provided between the bottom surface of the metal plate and the cooling surface, the adhesion member containing electrically conductive fillers that connect the bottom surface and the cooling surface.

2. The semiconductor device according to claim 1, wherein the electrically conductive fillers include fillers made of a metal.

3. The semiconductor device according to claim 2, wherein the metal is silver, copper, gold, nickel, chromium, aluminum, or an alloy containing at least one of silver, copper, gold, nickel, chromium or aluminum.

4. The semiconductor device according to claim 2, wherein the electrically conductive fillers are sintered to contact the bottom surface of the metal plate and the cooling surface.

5. The semiconductor device according to claim 1, wherein the adhesion member is made of the electrically conductive fillers and an organic resin containing a thermosetting resin as a major component.

6. The semiconductor device according to claim 5, wherein the thermosetting resin is an epoxy resin, a phenolic resin, or a polyimide resin.

7. The semiconductor device according to claim 1, wherein
the semiconductor module further includes an insulated circuit board, and
the insulated circuit board includes the metal plate, an insulating plate having a back surface on which the metal plate is placed and a front surface opposite to the back surface, and a conductive pattern placed on the front surface of the insulating plate.

8. The semiconductor device according to claim 7, wherein the insulating plate is made of insulating fillers and a resin as major components.

9. The semiconductor device according to claim 8, wherein the insulating plate has a linear expansion coefficient approximately equal to linear expansion coefficients of the conductive pattern and the metal plate.

10. The semiconductor device according to claim 7, wherein:
the semiconductor module further includes:
a semiconductor chip provided on the conductive pattern, and
a sealing member sealing the semiconductor chip and the insulated circuit board, and
the bottom surface of the metal plate is exposed from the sealing member.

11. The semiconductor device according to claim 10, wherein the adhesion member is in contact with the entire bottom surface of the metal plate exposed from the sealing member.

12. The semiconductor device according to claim 1, wherein the adhesion member has a thickness ranging from 50 μm to 150 μm, inclusive.

13. The semiconductor device according to claim 1, wherein the adhesion member has a thermal conductivity of 10 W/mK or more.

14. The semiconductor device according to claim 1, wherein the adhesion member has an adhesive strength of 10 MPa or more.

15. The semiconductor device according to claim 1, wherein the adhesion member has an elastic modulus of 10 GPa or less.
